(19) United States
(12) Patent Application Publication
(10) Pub. No.: US 2014/0152245 A1
(43) Pub. Date: Jun. 5, 2014

(54) CONTACTLESS POWER TRANSMISSION DEVICE

(71) Applicant: SAMSUNG ELECTRO-MECHANICS CO., LTD, Suwon (KR)

(72) Inventors: Kang Ryong CHOI, Suwon (KR); Seung Min KIM, Suwon (KR); Sung Yong AN, Suwon (KR); Chang Ryul JUNG, Suwon (KR)

(73) Assignee: SAMSUNG ELECTRO-MECHANICS CO., LTD, Suwon (KR)

(21) Appl. No.: 13/767,065

(22) Filed: Feb. 14, 2013

(30) Foreign Application Priority Data
Dec. 3, 2012 (KR) 10-2012-0139255

(51) Int. Cl. H05K 9/00; H04B 5/00; H02J 7/00

(52) U.S. Cl. CPC H05K 9/0081; H02J 7/0042; H04B 5/0037
USPC 320/108

(57) ABSTRACT

There is provided a contactless power receiver including a receiving coil part formed on a substrate, a magnetic receiving sheet positioned on the receiving coil part, a power storing part positioned on the magnetic receiving sheet, and a shielding layer positioned on the power storing part.

### CROSS-REFERENCE TO RELATED APPLICATIONS

This application claims the priority of Korean Patent Application No. 10-2012-0139255 filed on Dec. 3, 2012, in the Korean Intellectual Property Office, the disclosure of which is incorporated herein by reference.

### BACKGROUND OF THE INVENTION

1. Field of the Invention

The present invention relates to a contactless power transmission device capable of wirelessly transmitting power using electromagnetic induction.

2. Description of the Related Art

Research into a system for contactlessly transmitting power in order to charge a secondary battery embedded in a portable terminal or the like, with power, has been recently conducted.

A contactless power transmission device generally includes a contactless power transmitter transmitting power and a contactless power receiver receiving and storing power therein.

A contactless power transmission device transmits and receives power using electromagnetic induction. To this end, an inner portion of each of the contactless power transmitter and the contactless power receiver is provided with a coil.

A contactless power receiver configured of a circuit part and a coil part is attached to a cellular phone case or an additional accessory tool in a form of a cradle to implement a function thereof.

Describing an operational principle of the contactless power transmission device, household alternating current (AC) power supplied from the outside is input from a power supply unit of the contactless power transmitter.

The input household AC power is converted into direct current (DC) power by a power converting unit, is re-converted into AC voltage having a specific frequency, and is then provided to the contactless power transmitter.

When the AC voltage is applied to the coil part of the contactless power transmitter, a magnetic field around the coil part is changed.

As the magnetic field of the coil part of the contactless power receiver disposed to be adjacent to the contactless power transmitter is changed, the coil part of the contactless power receiver outputs power to charge the secondary battery with power.

Charging efficiency becomes higher as strength of the magnetic field becomes greater and is affected by a shape of the coil, an angle at which the coil of the contactless power receiver and the coil of the contactless power transmitter meet each other, and the like.

B=μ₀·n·i [Equation 1]

In a general case, the strength of the magnetic field is increased in proportion to vacuum magnetic permeability (μ₀), turns (n) of a solenoid winding, and an amount of flowing current (i) as represented by Equation 1.

B=μ·μ₀·n·i [Equation 2]

In the case in which a permanent magnet is positioned at the center of the coil, the strength of the magnetic field is increased in proportion to vacuum magnetic permeability (μ₀), turns (n) of a solenoid winding, an amount of flowing current (i), and magnetic permeability (μ) of the permanent magnet as represented by Equation 2.

According to the related art, in order to allow the coil of the contactless power receiver and the coil of the contactless power transmitter to coincide, the permanent magnet is positioned in a central portion of the coil of the contactless power receiver.

In this case, a magnetic field generated by the permanent magnet and a magnetic field induced in the coil, in the contactless power transmitter, have an effect on an electronic apparatus.

Therefore, according to the related art, a scheme of allowing a magnetic shield to be included in a central portion of the contactless power transmission device to keep a printed circuit board of the electronic apparatus from the magnetic field induced by the coil in the contactless power transmitter has been used.

However, as a result of measuring charging efficiency of the contactless power transmission device designed in the scheme according to the related art, it may be appreciated that an induction magnetic field passing through a ferrite sheet for charging generates eddy loss in the magnetic shield, such that the charging efficiency is rapidly decreased and the eddy loss is discharged as heat.

Therefore, a method capable of increasing the charging efficiency and preventing the magnetic field from reaching the electronic apparatus has been demanded.

In the invention disclosed in the following Related Art Document, relating to a contactless power charging device, a shield plate is positioned between a coil and a power storing part unlike in the case of the present invention.

As a result of measuring the charging efficiency in a state in which the shield plate is positioned between the coil and the power storing part as disclosed in the related art document below, it may be appreciated that the charging efficiency is 54.28%, significantly lower than that of a wired charging device.

### RELATED ART DOCUMENT

Korean Patent Laid-Open Publication No. 2010-0130480

### SUMMARY OF THE INVENTION

An aspect of the present invention provides a contactless power transmission device including an intermediate filled material such as a power storing part disposed between a magnetic sheet and a shielding layer.

Another aspect of the present invention provides a contactless power transmission device having high charging efficiency by adjusting a material and a thickness of a shielding layer and securing reliability by blocking an electronic apparatus from an influence of a magnetic field.

According to an aspect of the present invention, there is provided a contactless power receiver including: a receiving coil part formed on a substrate; a magnetic receiving sheet positioned on the receiving coil part; a power storing part positioned on the magnetic receiving sheet; and a shielding layer positioned on the power storing part.

A material of the shielding layer may be at least one of pure iron, a silicon steel alloy, an No—Fe—Mo alloy, and permalloy.

A thickness of the shielding layer may be 0.1 to 0.3 mm.

A material of the magnetic receiving sheet may be at least one of an Ni—Zn—Cu alloy and an Mn—Zn alloy.

The power storing unit may be a lithium ion secondary battery.

The contactless power receiver may further include an electronic apparatus positioned on the shielding layer.

According to another aspect of the present invention, there is provided a contactless power transmission device including: a contactless power receiver including a receiving coil part formed on a substrate, a magnetic receiving sheet positioned on the receiving coil part, a power storing part positioned on the magnetic receiving sheet, and a shielding layer positioned on the power storing part; and a contactless power transmitter including a permanent magnet.

A material of the shielding layer may be at least one of pure iron, a silicon steel alloy, an No—Fe—Mo alloy, and permalloy.

A thickness of the shielding layer may be 0.1 to 0.3 mm.

A material of the magnetic receiving sheet may be at least one of an Ni—Zn—Cu alloy and an Mn—Zn alloy.

The power storing unit may be a lithium ion secondary battery.

A material of the permanent magnet may be at least one of an Nd—Fe based magnet, a Sm₂Co₁₇ based magnet, a ferrite magnet, and an alnico magnet.

The contactless power transmission device may further include an electronic apparatus positioned on the shielding layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic exploded perspective view of a contactless power receiver according to an embodiment of the present invention; and

FIG. 2 is a schematic exploded perspective view of a contactless power transmission device including the contactless power receiver according to the embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

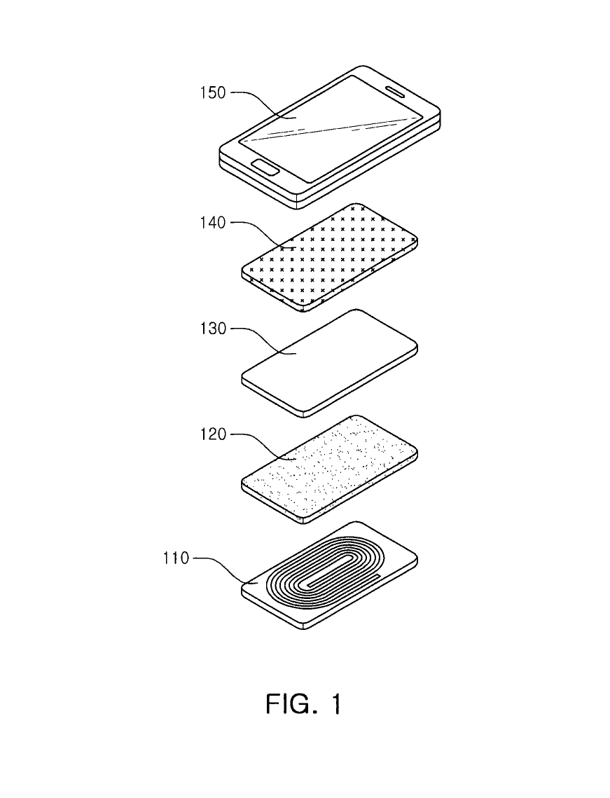

FIG. 1 is a schematic exploded perspective view of a contactless power receiver according to an embodiment of the present invention.

Referring to FIG. 1, the contactless power receiver according to the embodiment of the present invention may include a receiving coil part 110 formed on a substrate; a magnetic receiving sheet 120 positioned on the receiving coil part 110; a power storing part 130 positioned on the magnetic receiving sheet 120; and a shielding layer 140 positioned on the power storing part 130.

A shield according to the related art has been formed of a light flexible material by stacking a polyethylene terephthalate (PET) film and an amorphous tape, and the tape contains Fe, Si, B, Cu, Nb, or the like.

However, in the shield according to the related art, eddy loss is generated due to an induced magnetic field.

Particularly, since the eddy loss as described above is discharged as heat, in the case in which a magnetic sheet and the shield are directly adhered to each other, the shield according to the related art as described above may not be applied to an electronic apparatus such as a cellular phone.

Therefore, the shielding layer 140 is positioned on the power storing unit 130 positioned on the magnetic receiving sheet 120, whereby the generation of the eddy loss may be decreased.

The following Table 1 shows charging efficiency of the contactless power transmission device according to positions of the power storing unit 130 and the shield layer 140.

TABLE 1

| | Charging efficiency |
|---|---|
| Comparative Example 1 | 74.88% |
| Comparative Example 2 | 54.82% |
| Inventive Example | 69.78% |

Comparative Example 1 is an example of a contactless power receiver including a transmitting coil part and a magnetic sheet positioned on the transmitting coil part.

Comparative Example 2 is an example of a contactless power receiver including a transmitting coil part, a magnetic sheet positioned on the transmitting coil part, and an iron shielding layer positioned on the magnetic sheet.

Inventive Example is an example of a contactless power receiver including the transmitting coil part 110, the magnetic sheet positioned on the transmitting coil part 110, a lithium-ion battery positioned on the magnetic sheet, and the iron shielding layer positioned on the lithium-ion battery, similar to the embodiment of the present invention.

Charging efficiency has been shown using a percentage as compared with a wired charger.

As seen in Table 1, the charging efficiency of the contactless power receiver according to Comparative Example 1 in which the shielding layer is not used is 74.88%, a very high level.

However, in the contactless power receiver according to Comparative Example 1, since the shielding layer is not present, a magnetic field has a direct effect on an electronic apparatus to rapidly decrease reliability of the electronic apparatus, such that it is difficult to actually commercialize the contactless power receiver according to Comparative Example 1.

In the contactless power receiver according to Comparative Example 2, since the shielding layer is used, an effect of a magnetic field on the electronic apparatus is decreased; however, the charging efficiency is rapidly decreased to 54.82%.

By comparison, in the contactless power receiver according to Inventive Example, since the iron shield layer is positioned on the battery, an effect of a magnetic field on the electronic apparatus is decreased, whereby reliability may be secured.

Further, since the charging efficiency also is 69.78%, relatively, sufficiently high, charging efficiency and reliability of the contactless power transmission device may be secured.

A material of the shielding layer 140 may be at least one of pure iron, a silicon steel alloy, an No—Fe—Mo alloy, and permalloy, but is not limited thereto.

A material of the shielding layer 140 may have magnetic permeability of 100 or more.

The metal such as pure iron, a silicon steel alloy, an No—Fe—Mo alloy and permalloy as described above may a metal having relatively high magnetic permeability in a predetermined frequency region (DC to 20 MHz), but is not limited thereto.

The receiving coil part 110 may include a single coil formed in a wiring pattern form on the substrate or a single coil formed by connecting a plurality of coil strands in parallel with one another.

The receiving coil part 110 may be manufactured in winding form or be manufactured in a flexible film form, but is not limited thereto.

The coil part transmits input power using an induced magnetic field or receives the induced magnetic field to allow the power to be output, thereby enabling contactless power transmission.

The contactless power receiver may include the magnetic receiving sheet 110 positioned on the receiving coil part 100 in order to increase a communication distance.

The magnetic receiving sheet 120 may be a high magnetic permeability ferrite sheet used as an electromagnetic wave countermeasure, a heat radiation countermeasure, or the like, in the contactless power transmission device.

A material of the magnetic receiving sheet 120 may be at least one of an Ni—Zn—Cu alloy and an Mn—Zn alloy, but is not limited thereto.

Household alternating current (AC) power supplied from the outside is input to a power supply unit of the contactless power transmitter.

The input household AC power is converted into direct current (DC) power by a power converting unit, is re-converted into AC voltage having a specific frequency, and is then provided to the contactless power transmitter.

When the AC voltage is applied to a transmitting coil part of the contactless power transmitter, a magnetic field around the transmitting coil part may be changed. Therefore, a magnetic field of the receiving coil part of the contactless power receiver disposed to be adjacent to the contactless power transmitter is changed, such that the receiving coil part 110 of the contactless power receiver may output power.

The power storing part 130 receives the power output from the receiving coil part 110 of the contactless power receiver, and stores the power therein, and the stored power is used at the time of operation of the electronic apparatus, or the like.

The power storing unit 130 may be a lithium ion secondary battery.

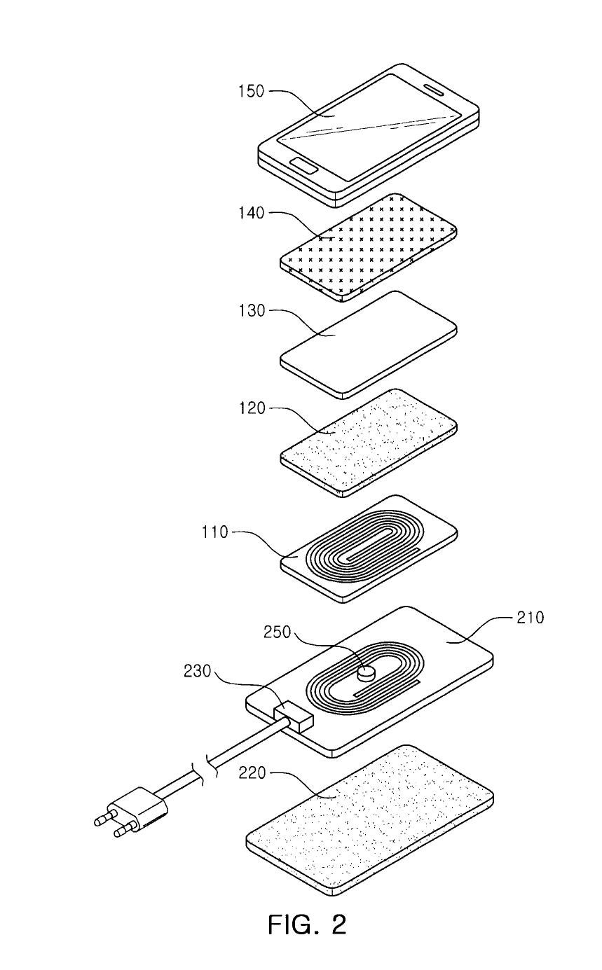

FIG. 2 is a schematic exploded perspective view of a contactless power transmission device including the contactless power receiver according to the embodiment of the present invention.

Referring to FIG. 2, the contactless power transmission device according to another embodiment of the present invention may include a contactless power receiver including a receiving coil part 110 formed on a substrate, a magnetic receiving sheet 120 positioned on the receiving coil part 110, a power storing part 130 positioned on the magnetic receiving sheet 120, and a shielding layer 140 positioned on the power storing part 130; and a contactless power transmitter including a permanent magnet 250.

Generally, in the contactless power transmission device, in order to allow a transmitting coil part 210 of the contactless power transmitter and a receiving coil part 110 of the contactless power receiver to coincide with each other, the permanent magnet 250 is positioned in the contactless power transmitter.

The permanent magnet 250 may be a magnet in which a change in strength of residual magnetization due to external magnetic disturbance is relatively low.

In addition, the permanent magnet 250 may be any one of an Nd—Fe based magnet, a Sm₂Co₁₇ based magnet, a ferrite magnet, and an alnico magnet, but is not limited thereto.

The permanent magnet 250 may serve to allow the center of the receiving coil part 110 and the center of the transmitting coil part 210 to coincide with each other.

The permanent magnet 250 may discharge a magnetic field of about 77.5 mT, which has an effect on a printed circuit board (PCB), a digitizer, a near field communication (NFC) module, and the like, of the electronic apparatus 150 such as a cellular phone.

Therefore, the shielding layer 140 may be positioned under the electronic apparatus 150 to shield the magnetic field discharged by the permanent magnet 250, thereby securing reliability of the electronic apparatus 150.

A thickness of the shielding layer 140 may be 0.1 to 0.3 mm.

Generally, the thicker the shielding layer 140, the higher the shielding effectiveness.

However, since the electronic apparatus 150, such as a cellular phone, a smart phone, a tablet personal computer, or the like, has been recently miniaturized and thinned gradually, it may be difficult to infinitely increase a thickness of the shielding layer 140.

That is, in the case in which the thickness of the shielding layer 140 exceeds 0.3 mm, it is difficult to use the shielding layer 140 in the electronic apparatus 150, or the like, such that commercialization properties of the shielding layer 140 may be rapidly decreased.

Further, in the case in which the thickness of the shielding layer 140 is less than 0.1 mm, a leakage magnetic flux may become 16 mT or more in a magnetic flux of 77.5 mT discharged by the permanent magnet 250, such that a magnetic field has an effect on the electronic apparatus 150, thereby decreasing reliability.

Therefore, in the case in which the thickness of the shielding layer 140 is 0.1 to 0.3 mm, the leakage magnetic flux is less than 16 mT, such that reliability of the electronic apparatus 150 may be secured. Further, a commercialization property of the shielding layer 140 is secured, such that the shielding layer 140 may be used in the electronic apparatus 150 that has been recently miniaturized and thinned.

The following Table 2 shows a measurement result of a leakage magnetic flux according to a material and a thickness of the shielding layer 140.

TABLE 2

| | | Leakage | Initial | |
|---|---|---|---|---|
| | Thickness | magnetic flux | magnetic | Bmax |
| | (mm) | (mT) | permeability | (KG) |
| Comparative | 0.30 | 28.6 | 250 | 22 |
| Example 1 | | | | |
| Comparative | 0.60 | 9.0 | 250 | 22 |
| Example 2 | | | | |
| Comparative | 0.15 | 47.8 | 30,000 | 8 |
| Example 3 | | | | |
| Inventive | 0.10 | 15.4 | 1500 | 20 |
| Example 1 | | | | |
| Inventive | 0.30 | 12.3 | 1500 | 20 |
| Example 2 | | | | |

In order to measure the leakage magnetic flux according to Comparative Examples and Inventive Examples, magnetic flux having the same magnitude as that of 77.5 mT discharged by the permanent magnet 250 used in the contactless power transmitter has been applied to measure leakage magnetic flux according to the shielding layer.

In Comparative Example 1, a material of the shielding layer is a steel alloy, and a thickness thereof is 0.30 mm.

In Comparative Example 2, a material of the shielding layer is a steel alloy, and a thickness thereof is 0.60 mm.

In Comparative Example 3, a material of the shielding layer is permalloy, and a thickness thereof is 0.15 mm.

In Inventive Example 1, an example of the shielding layer according to the embodiment of the present invention, a thickness of the shielding layer is 0.10 mm.

In Inventive Example 2, an example of the shielding layer according to the embodiment of the present invention, a thickness of the shielding layer is 0.30 mm.

Referring to Comparative Examples 1 and 2, it may be appreciated that as the thickness of the shielding layer becomes thicker, the leakage magnetic flux is rapidly decreased.

In Comparative Example 2, even in the case in which the leakage magnetic flux is 9.0 mT, relatively very low, the thickness of the shielding layer 140 is 0.60 mm, which exceeds 0.30 mm, such that commercialization properties are relatively low.

In Comparative Example 3, although the thickness of the shielding layer 140 is 0.15 mm, thin enough to actually apply the shielding layer to the electronic apparatus, the leakage magnetic flux is 47.8 mT, relatively very high. Therefore, in this case, in the case in which the shielding layer is actually used in the electronic apparatus, a magnetic field has an effect on the electronic apparatus to decrease reliability of the electronic apparatus.

Referring to Inventive Examples 1 and 2, since the shielding layer according to the embodiment of the present invention has a leakage magnetic flux less than 16 mT, the reliability of the electronic apparatus may be secured.

Further, the shielding layer according to the embodiment of the present invention also has a thickness of 0.10 to 0.30 mm, whereby commercialization properties according to miniaturization and thinness of the electronic apparatus may be secured.

The contactless power transmitter may include a transmitting magnetic sheet 220.

The transmitting magnetic sheet 220 may prevent an induced magnetic field from being leaked to a rear surface at the time of operation of the contactless power transmitter to contribute to an increase in a power transmission distance and an increase in charging efficiency.

The contactless power transmitter may include a power input unit 230.

The power input unit 230 may convert household AC power into DC power, re-convert the DC power into AC power having a specific frequency, and then transfer the AC power having the specific frequency to the transmitting coil part 210.

The AC power having the specific frequency as described above is applied to generate an induced magnetic field in the transmitting coil part 210, whereby the contactless power transmission device may be operated.

The contactless power transmission device according to the embodiment of the present invention described above is not limited to the above-mentioned embodiments, but may be variously applied.

In addition, although the contactless power receiver used in the electronic apparatus has been described in the above-mentioned embodiments by way of example, the contactless power receiver according to the embodiments of the present invention is not limited thereto, but may be widely used in all electronic apparatuses capable of being used by charging power therein and all power transmission devices capable of transmitting the power.

As set forth above, according to the embodiments of the present invention, the contactless power transmission device having charging efficiency corresponding to 69% or more of the charging efficiency of the wired charging device may be provided.

In addition, according to the embodiments of the present invention, the contactless power transmission device capable of having relatively high charging efficiency and preventing damage to the electronic apparatus due to a magnetic field and heat may be provided.

While the present invention has been shown and described in connection with the embodiments, it will be apparent to those skilled in the art that modifications and variations can be made without departing from the spirit and scope of the invention as defined by the appended claims.

What is claimed is:

1. A contactless power receiver comprising:
a receiving coil part formed on a substrate;
a magnetic receiving sheet positioned on the receiving coil part;
a power storing part positioned on the magnetic receiving sheet; and
a shielding layer positioned on the power storing part.

2. The contactless power receiver of claim 1, wherein a material of the shielding layer is at least one of pure iron, a silicon steel alloy, an No—Fe—Mo alloy, and permalloy.

3. The contactless power receiver of claim 1, wherein a thickness of the shielding layer is 0.1 to 0.3 mm.

4. The contactless power receiver of claim 1, wherein a material of the magnetic receiving sheet is at least one of an Ni—Zn—Cu alloy and an Mn—Zn alloy.

5. The contactless power receiver of claim 1, wherein the power storing unit is a lithium ion secondary battery.

6. The contactless power receiver of claim 1, further comprising an electronic apparatus positioned on the shielding layer.

7. A contactless power transmission device comprising:
a contactless power receiver including a receiving coil part formed on a substrate, a magnetic receiving sheet positioned on the receiving coil part, a power storing part positioned on the magnetic receiving sheet, and a shielding layer positioned on the power storing part; and
a contactless power transmitter including a permanent magnet.

8. The contactless power transmission device of claim 7, wherein a material of the shielding layer is at least one of pure iron, a silicon steel alloy, an No—Fe—Mo alloy, and permalloy.

9. The contactless power transmission device of claim 7, wherein a thickness of the shielding layer is 0.1 to 0.3 mm.

10. The contactless power transmission device of claim 7, wherein a material of the magnetic receiving sheet is at least one of an Ni—Zn—Cu alloy and an Mn—Zn alloy.

11. The contactless power transmission device of claim 7, wherein the power storing unit is a lithium ion secondary battery.

12. The contactless power transmission device of claim 7, wherein a material of the permanent magnet is at least one of an Nd—Fe based magnet, Sm₂Co₁₇ based magnet, a ferrite magnet, and an alnico magnet.

13. The contactless power transmission device of claim 7, further comprising an electronic apparatus positioned on the shielding layer.
